(19) United States
(12) Patent Application Publication
(10) Pub. No.: US 2025/0388454 A1
(43) Pub. Date: Dec. 25, 2025

(54) MEMS ELEMENT

(71) Applicant: Nisshinbo Micro Devices Inc., Tokyo (JP)

(72) Inventors: Takao FUKUTOME, Fujimino-shi, Saitama (JP); Keita YAMAMOTO, Fujimino-shi, Saitama (JP)

(73) Assignee: Nisshinbo Micro Devices Inc., Tokyo (JP)

(21) Appl. No.: 18/879,296

(22) PCT Filed: Jul. 22, 2022
(86) PCT No.: PCT/JP2022/028508

§ 371 Date: Dec. 27, 2024

(51) Int. Cl. B81B 3/00; H04R 19/00; H04R 19/04

(52) U.S. Cl. CPC B81B 3/0021; H04R 19/005; H04R 19/04; B81B 2201/0257; B81B 2203/0127; B81B 2203/04; B81B 2207/053

(57) ABSTRACT

A MEMS element is provided in which, a backplate including a fixed electrode and a vibrating membrane including a movable electrode are disposed facing each other; the vibrating membrane is provided with a pillar connected to the backplate, a pillar side slit and a peripheral portion side slit; and on the vibrating membrane vibrating portions and fixed electrode portions facing the vibrating portions are formed. A central portion of the vibrating membrane is connected to the backplate by the pillar, and thereby the amplitude of the central portion can be suppressed. In each of the vibrating portions, the pillar side slit is formed in the vicinity of a joint portion of the pillar and the vibrating membrane and a peripheral portion side silt is formed at the peripheral portion, and thereby a difference of the amplitude amount between the central portion and the peripheral portion is decreased.

### TECHNICAL FIELD

The present disclosure relates to a capacitance-type MEMS element used as a microphone, various sensors, and the like.

### BACKGROUND ART

As a MEMS (Micro Electro Mechanical Systems) element using a semiconductor process, a capacitance-type MEMS element is known, in which a backplate including a fixed electrode equipped with a plurality of acoustic holes and a vibrating membrane including a movable electrode are disposed on a substrate across an insulating film to be a spacer.

The capacitance-type MEMS element is configured to detect, as a capacitance change between the movable electrode and the fixed electrode, a displacement of the movable electrode caused by a vibration of the vibrating membrane and output a detection signal. This type of MEMS element is disclosed in Patent Document 1, for example.

### PRIOR ART DOCUMENT

### Patent Document

Patent Document 1: JP 2011-55087 A

### SUMMARY OF THE INVENTION

### Problem to be Solved by the Invention

FIG. 13 shows a schematic cross-sectional view for explaining a conventional MEMS element, for example. As shown in FIG. 13, in a conventional MEMS element 300, an insulating film 32 is formed on a substrate 31 as a support substrate, and on the insulating film 32, a vibrating membrane 33 including a conductive movable electrode is formed. Further, a spacer 34 constituted by an insulating film and a backplate 37 constituted by a conductive fixed electrode 35 and an insulating film 36 are laminated, forming an air gap structure. Letter 38 denotes an acoustic hole formed in the backplate 37, letter 39 denotes a back chamber formed in the substrate 31, letter 40 denotes a slit formed at the peripheral portion of the vibrating membrane 33, letter 41 denotes a movable electrode output terminal connected to the vibrating membrane 33 as a movable electrode, and letter 42 denotes a fixed electrode output terminal connected to the fixed electrode 35.

FIG. 14 is a schematic plan view explaining a positional relationship of the fixed electrode 35 relative to the vibrating membrane 33 in the MEMS element 300 shown in FIG. 13. In FIG. 14, a broken line A shows a joint portion between the vibrating membrane 33 and the spacer 34 (or an outer periphery of the back chamber 39), and in a case where a portion corresponding to the back chamber 39 has a circular shape, the broken line A forms a circular shape (note that a slit 40 is not shown). The vibrating membrane 33 including a conductive movable electrode is connected to the movable electrode output terminal 41 formed on the surface of the MEMS element 300 via a through electrode formed on the spacer 34. The fixed electrode 35 is connected to the fixed electrode output terminal 42 via a wire 43. When the vibrating membrane 33 vibrates by receiving a sound pressure and the like in a state where a predetermined bias volage is applied to the vibrating membrane 33 (movable electrode) and the fixed electrode 35 from the movable electrode output terminal 41 and the fixed electrode output terminal 42, a voltage change occurs depending on a vibration magnitude of the vibrating membrane 33 and thereby a detection signal can be obtained. The detection signal is output from the fixed electrode output terminal 42 to an integrated circuit device in which a signal process circuit performing a desired signal processing is formed, for example.

FIG. 15 is a view explaining vibration characteristics of the vibrating membrane 33 in the MEMS element 300 shown in FIG. 13. The vertical axis in FIG. 15 is an amplitude amount, representing a relative amount assuming that a maximum amplitude is 1.00. The horizontal axis in FIG. 15 is a radial distance from the center of the vibrating membrane 33, representing a relative distance assuming that the center of the vibrating membrane 33 is 0.00 and a portion corresponding to the outer periphery of the back chamber of the vibrating membrane 33 in FIG. 14 is 1.00. As shown in FIG. 15, the central portion of the vibrating membrane 33 vibrates in a large amount and the amplitude amount in the peripheral portion thereof is small. Accordingly, the fixed electrode 35 is disposed in a region facing the central portion of the vibrating membrane 33 that vibrates in a large amount as shown in FIG. 13 and FIG. 14. Generally, a fixed electrode is formed in a region where the distance from the center of the vibrating membrane is 0.40-0.70 on the horizontal axis in FIG. 15. This is because a capacity change due to vibration of a vibrating membrane is small if a fixed electrode is disposed in a region where the vibration amplitude is small, and thereby it becomes a parasitic capacity causing a decreased sensitivity.

Further, if the vibrating membrane 33 displaces in a large amount and a difference in amplitude amount is generated between the central portion of the vibrating membrane 33 with a large amount of displacement and the peripheral portion with a small amount of displacement, an area of the vibrating membrane 33 being displaced in parallel relative to the fixed electrode 35 becomes small within a region of the vibrating membrane 33 facing the fixed electrode 35. As a result, a detection signal becomes nonlinear, which can cause deterioration in the AOP (Acoustic Over Load Point).

However, in the case where a capacitance-type MEMS element is used as a microphone, an improvement in the AOP is required while suppressing the reduction in sensitivity as much as possible, and of course, an improved the SNR (Signal-Noise Ratio) is also required.

Therefore, a problem to be solved by the present disclosure is to provide a MEMS element having an excellent sensitivity and improved the AOP and the SNR characteristics.

### Means to Solve the Problem

A MEMS element of the present disclosure, in one embodiment, comprises: a substrate comprising a back chamber; a vibrating membrane joined onto the substrate, wherein the vibrating membrane comprises a movable electrode; and a backplate comprising a fixed electrode disposed so as to face the movable electrode, wherein the vibrating membrane: has, at a central portion thereof, a pillar that connects the backplate and the vibrating membrane; and has a plurality of vibrating portions in a region between a portion in which the pillar and the vibrating membrane are joined and a peripheral portion of the vibrating membrane, wherein each of the plurality of vibrating portions is formed by a region surrounded by a pillar side slit by a first slit portion and a second slit portion joined and a peripheral portion side slit disposed at the peripheral portion between an extension line toward the peripheral portion from the first slit portion and an extension line toward the peripheral portion from the second slit portion, the first slit portion and the second slit portion extending in mutually different directions toward the peripheral portion from a portion side in which the pillar and the vibrating membrane are joined, and wherein the fixed electrode has a plurality of fixed electrode portions, each of which is disposed in a region facing each of the plurality of vibrating portions.

### Effects of the Invention

According to the MEMS element of the present disclosure, the central portion of a vibrating membrane is joined to the backplate by the pillar, so that the amplitude of the central portion of the vibrating membrane is suppressed, and further the vibrating membrane is provided with slits on the vibrating membrane, the vibrating portion with a small difference in amplitude amount between the central portion and the peripheral portion of the vibrating membrane can be formed. On the vibrating membrane, a plurality of the vibrating portions is formed, and the fixed electrode portion is disposed in each of regions facing each of the plurality of vibrating portions, so that a large detection signal can be obtained as a whole. Further, by dividing the vibrating portion into a plurality of vibrating portions each having a small area, a force applied on each of the vibrating portions is reduced when a bias voltage is applied between the fixed electrode portion and the movable electrode and thereby distortion of a detection signal is reduced. Furthermore, by dividing the fixed electrode into a plurality of fixed electrode portions and thereby providing a configuration in which a plurality of variable capacitance elements is connected in parallel, a detection signal with a low noise can be obtained. In this way, according to the present disclosure, it is possible to provide a MEMS element that can improve the AOP and further the SNR characteristics without reducing sensitivity. As a result, a MEMS element for a high-performance microphone can be obtained.

### BRIEF DESCRIPTION OF THE DRAWINGS

FIG. 1 is a schematic cross-sectional view of a MEMS element being one embodiment (Embodiment 1) of the present disclosure.

FIG. 2 is a schematic plan view explaining vibrating membrane portions in Embodiment 1.

FIG. 3 is a schematic plan view explaining an arrangement of the vibrating membrane portions and fixed electrode portions in Embodiment 1.

FIG. 4 is a view explaining vibration characteristics of the vibrating portion in Embodiment 1.

FIG. 5 is a view explaining vibration characteristics of the vibrating portion in Embodiment 1.

FIG. 6 is a view explaining vibration characteristics of the vibrating portion in Embodiment 1.

FIG. 7 is a view explaining vibration characteristics of the vibrating portion in Embodiment 1.

FIG. 8 is a schematic plan view explaining an arrangement of vibrating membrane portions and fixed electrode portions in a MEMS element in another embodiment (Embodiment 2) of the present disclosure.

FIG. 9 is a schematic cross-sectional view of a MEMS element in a further embodiment (Embodiment 3) of the present disclosure.

FIG. 10 is a schematic plan view explaining an arrangement of vibrating membrane portions and fixed electrode portions in Embodiment 3.

FIG. 11 is a view explaining a MEMS apparatus using a MEMS element of the present disclosure.

FIG. 12 is a view explaining another MEMS apparatus using a MEMS element of the present disclosure.

FIG. 13 is a schematic cross-sectional view of a conventional MEMS element.

FIG. 14 is a schematic plan view explaining an arrangement of a vibrating membrane portion and a fixed electrode portion in a conventional MEMS element.

FIG. 15 is a view explaining vibration characteristics of a vibrating membrane in a conventional MEMS element.

### EMBODIMENT FOR CARRYING OUT THE INVENTION

Then, embodiments of a MEMS element of the present disclosure are explained with reference to the drawings, but the present disclosure is not limited to these embodiments, and members, materials, and the like described below can be variously modified within the range of the gist of the present disclosure. Further, a same reference numeral in the drawings indicates an equivalent or the same component, and a size, a positional relationship, and the like of each component in the drawings are merely for the purpose of convenience and do not reflect their actual states.

### Embodiment 1

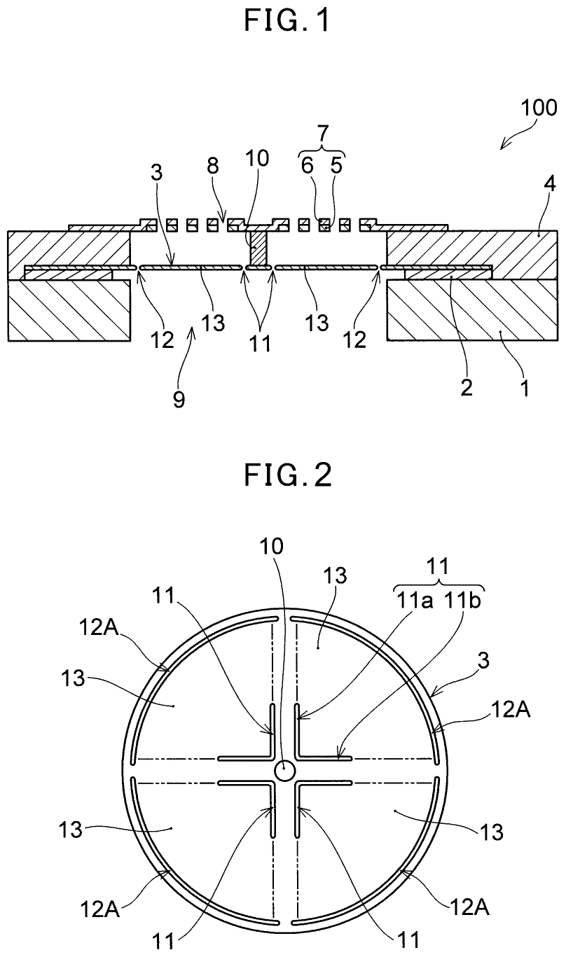

FIG. 1 is a schematic cross-sectional view for explaining Embodiment 1 of a MEMS element of the present disclosure. As shown in FIG. 1, in one embodiment of a MEMS element 100 of the present disclosure, an insulating film 2 composed of a thermal oxide film and the like, for example, is formed on a substrate 1 as a support substrate, which is composed of a silicon substrate and the like, for example, and a vibrating membrane 3 including a conductive movable electrode composed of polysilicon and the like, for example, is formed on the insulating film 2. Moreover, an insulating spacer 4 and a backplate 7 are laminated, the insulating spacer 4 being composed of a USG (Undoped Silicate Glass) film and the like, for example, and the backplate 7 including a conductive fixed electrode 5 composed of polysilicon and the like, for example, and an insulating film 6 composed of a silicon nitride and the like, for example. Letter 8 denotes an acoustic hole, and letter 9 denotes a back chamber formed in the substrate 1.

In the MEMS element 100 in the present embodiment, the vibrating membrane 3 and the insulating film 6 constituting the backplate 7 are jointly connected to a pillar 10, respectively, and the vibrating membrane 3 is provided with pillar side slits 11 and peripheral portion side slits 12.

FIG. 2 is a schematic plan view explaining a vibrating membrane portion of the MEMS element 100 shown in FIG. 1, in which an arrangement of the pillar 10, the pillar side slits 11 and the peripheral portion side slits 12A is explained. The back chamber 9 formed in the substrate 1 in FIG. 1 has a circular shape, and the outer periphery in FIG. 2 corresponds to the outer periphery of the back chamber 9 on the substrate 1. The schematic cross-sectional view shown in FIG. 1 corresponds to the cross-sectional view in FIG. 2 crossing along the center of the pillar 10 and the two pillar side slits 11 facing each other with the pillar 10 as the center.

As shown in FIG. 2, in a case where a portion corresponding to the back chamber 9 of the vibrating membrane 3 has a circular shape, the pillar 10 is disposed on the vibrating membrane 3 in a manner that the center of the vibrating membrane 3 and the center of the circular pillar 10 match each other, and the pillar side slits 11 and the peripheral portion side slits 12A are disposed to surround the pillar 10 in an evenly spaced manner. In the vibrating membrane 3 configured in this way, four vibrating portions 13 are formed in regions between the joint portion with the pillar 10 and the peripheral portion.

A detailed description is given referring to one vibrating portion 13 as an example. In a region on the upper right side of the pillar 10 of the vibrating membrane 3 shown in FIG. 2, the pillar side slit 11 is formed by a first slit portion 11a and a second slit portion 11b, in which the first slit portion 11a is parallel in the radial direction of the vibrating membrane 3 from the pillar 10 side and extends in the upper direction of the drawing, and the second slit portion 11b is parallel in the radial direction of the vibrating membrane 3 from the pillar 10 side and extends in the rightward direction of the drawing so as to joint with the first slit portion 11a at a joint angle 90 degrees.

By forming the pillar side slits 11, vibration is facilitated at a portion of the vibrating membrane 3 on the pillar 10 side where the vibration is limited by the pillar 10.

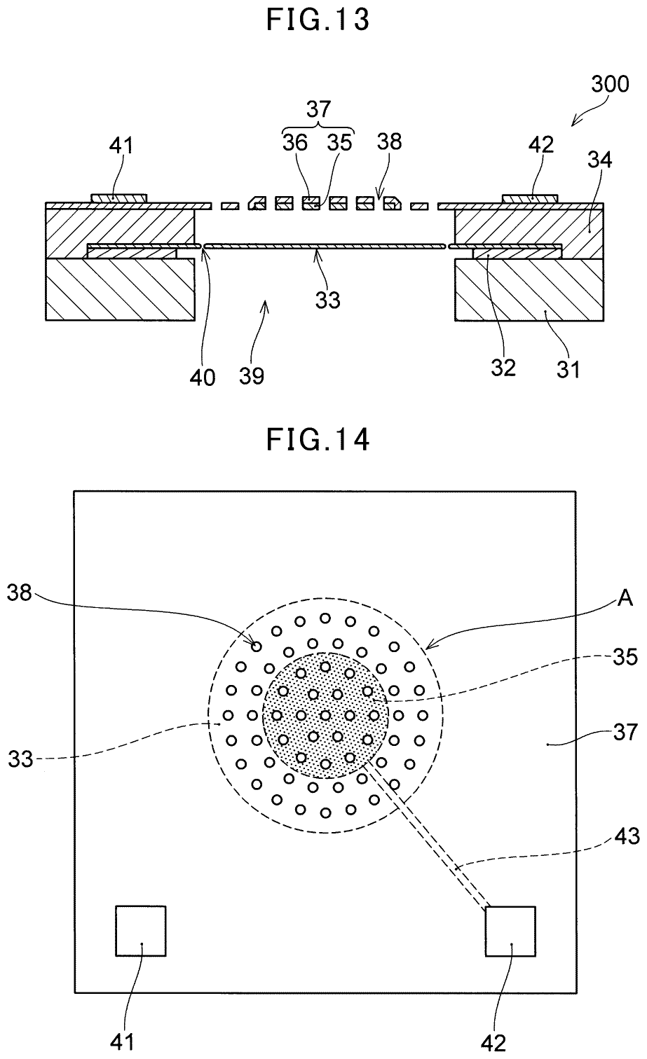

Further, peripheral portion side slits 12A are formed on the peripheral portion where the vibrating membrane 3 is joined onto the substrate 1, the insulating film 2, and the spacer 4, and thereby vibration at the peripheral portion of the vibrating membrane 3, where vibration is limited due to the joint with the substrate 1 and the like, is facilitated. The peripheral portion side slits 12A have a similar effect to the slits 40 formed on the typical MEMS element 300 explained in FIG. 13, and particularly, in the peripheral portion side slits 12A of the present embodiment, each of regions surrounded by an extension line of the first slit portion 11a in an extending direction and an extension line of the second slit portion 11b in an extending direction, which are shown with a double-dashed line in FIG. 2, respectively, forms one vibrating portion 13, and therefore, the peripheral portion side slits 12A are formed so as to open up to a position or near to the position where both ends of the respective peripheral portion side slits intersect with the above-described extension lines.

In this way, the region surrounded by the pillar side slit 11 and the peripheral portion side slit 12A forms one vibrating portion 13. The plurality of vibrating portions 13 are disposed to surround the center of the pillar 10 (the center of the vibrating membrane 3) in an evenly spaced manner, and thereby form four vibrating portions 13 having the same characteristics.

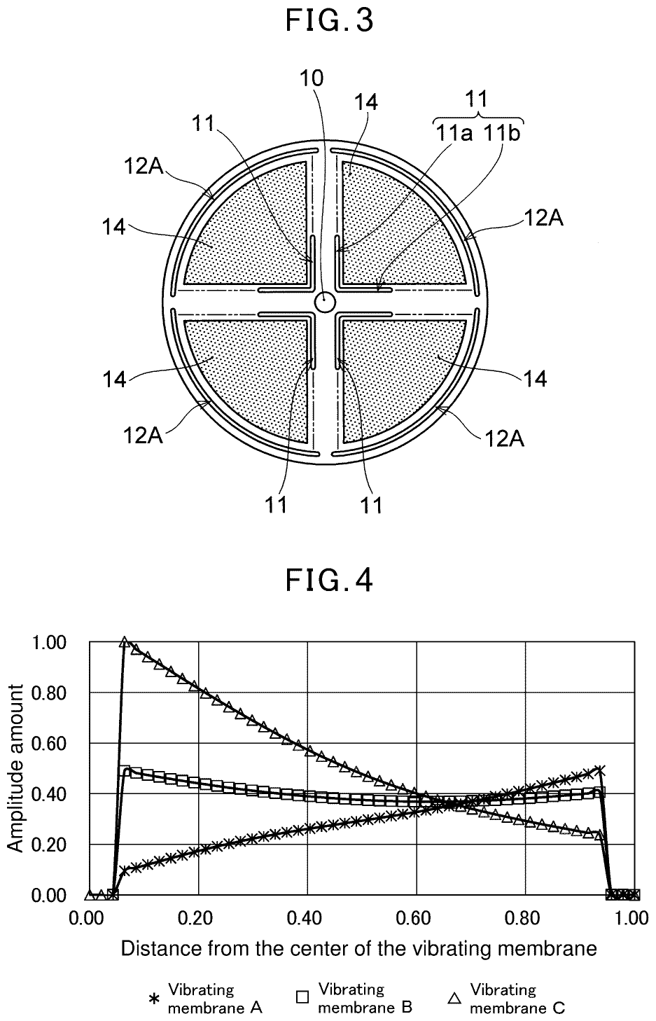

FIG. 3 is a schematic plan view explaining an arrangement of the vibrating membrane portion and the fixed electrode portion in the MEMS element 100 shown in FIG. 1, in which an arrangement of the vibrating membrane 3 on which the pillar 10, the pillar side slits 11, and the peripheral portion side slits 12A are disposed, as well as the fixed electrode portions 14, is explained. The fixed electrode 5 shown in FIG. 1 is configured by the plurality of fixed electrode portions 14 disposed in a region facing each of the plurality of vibrating portions 13 explained in FIG. 2. The MEMS element 100 of the present embodiment shown in FIG. 3 is configured to form four fixed electrode portions 14 thereon. As described above, the region surrounded by the pillar side slit 11 formed by the first slit portion 11a and the second slit portion 11b and the peripheral portion side slit 12A is defined as one vibrating portion 13 (not shown in FIG. 3). Accordingly, the fixed electrode portions 14 are disposed in regions facing the regions surrounded by the pillar side slits 11 formed by the first slit portions 11a and the second slit portions 11b as well as the peripheral portion side slits 12A, and each of the plurality of fixed electrode portions 14 is disposed so as to face each of the vibrating portions 13. It should be noted that an acoustic hole formed in the fixed electrode portion 14 is not shown in FIG. 3. Further, a wire connecting each of the fixed electrode portions 14 and a fixed electrode output terminal is not shown. The connection between each of the fixed electrode portions 14 and the fixed electrode output terminal will be described below.

Then, the vibration characteristics of the vibrating portions are explained with a reference to an example of vibration characteristics of one vibrating portion 13. The vibration characteristics of the vibrating portion 13 change depending on a material constituting the vibrating membrane 3, a thickness and a size thereof. Further, the vibration characteristics can be changed depending on shape of the pillar side slit 11 and the peripheral portion side slit 12A.

FIGS. 4 to 7 are views explaining the vibration characteristics of vibrating portion 13 of the MEMS element 100 in the present embodiment. The vertical axis in FIG. 4 represents an amplitude amount relative to the maximum amplitude being assumed as 1.00. The horizontal axis in FIG. 4 represents a distance from the center of the vibrating membrane 3 in the radial direction of the vibrating membrane 3 from the center of the pillar 10 through the joint portion between the first slit portion 11a and the second slit portion 11b of the pillar side slit 11, which is a relative distance assuming that the center of the pillar 10 is 0.00 and the outer periphery shown in FIG. 2 is 1.00. In FIG. 4, amplitude amounts of the vibrating portions 13 are compared when changing the length of the pillar side slit 11 in the extending direction to 19% (a vibrating membrane A), 38% (a vibrating membrane B), and 56% (a vibrating membrane C). Here, the length of the pillar side slit 11 in the extending direction is represented in a ratio assuming that the length from the center of the pillar 10 to the outer periphery shown in FIG. 2 is 100. The same conditions are set in the comparison except for the length of the pillar side slit 11 in the extending direction.

As shown in FIG. 4, it is seen that all of them vibrate between the pillar side slit 11 and the peripheral portion side slit 12A. Further, it is seen that the longer the length of the pillar side slit 11 is (the slit length: the vibrating membrane A<the vibrating membrane B<the vibrating membrane C), the larger the amplitude amount near the pillar side slit 11 becomes (the amplitude amount: the vibrating membrane A<the vibrating membrane B<the vibrating membrane C). Furthermore, it is seen that the each of the amplitude amounts near the peripheral portion side slit 12A also change.

Particularly for the vibrating membrane B, it is seen that a vibration causing a generally uniform amplitude amount occurs throughout the vibrating portion 13 between the pillar side slit 11 and the peripheral portion side slit 12A. This indicates that the movable electrode of the vibrating portion 13 (the vibrating membrane 3) is displaced generally in parallel to the fixed electrode portions 14 facing thereto. Accordingly, in the present embodiment, the vibrating membrane B is preferably defined as a slit length of the pillar side slit 11, among the vibrating membranes A-C, in view of an improvement in AOP.

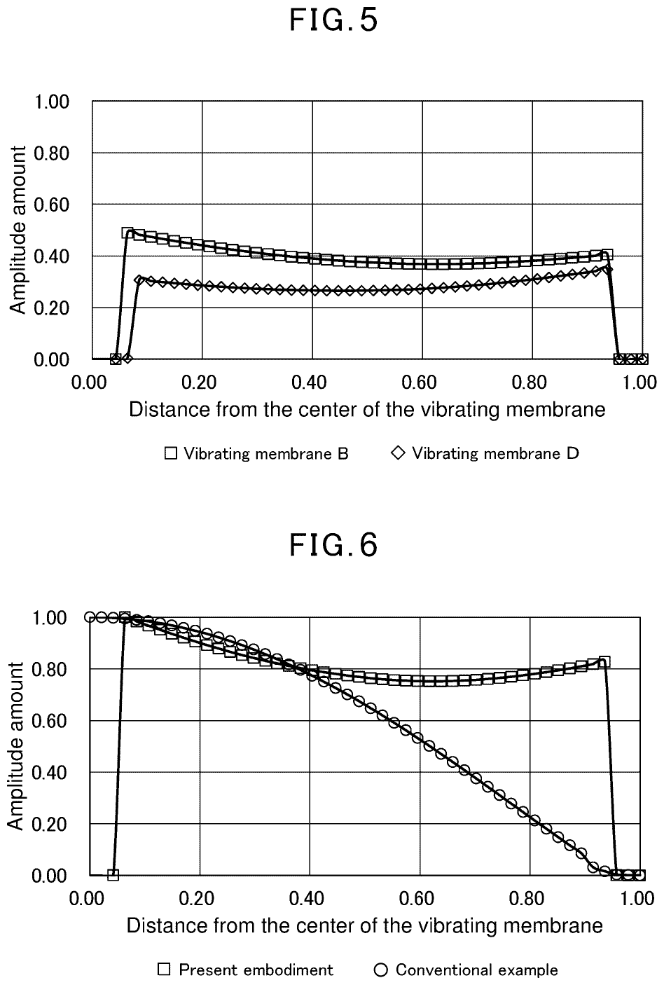

An adjustment of the vibration characteristics of the vibrating portion 13 is not limited to the adjustment by the length of the pillar side slit 11 as explained in FIG. 4. The vibration characteristics of the vibrating portion 13 can also be adjusted by a change in arrangement of the pillar side slit 11. In FIG. 5, the vibrating membrane B shown in FIG. 4 is compared with amplitude amounts of the vibrating portion 13 in a vibrating membrane D that is in a case in which the conditions such as the slit length and the like are set to be identical to those of the vibrating membrane B and the pillar side slit 11 is moved toward the peripheral portion side by a few percent of what is from the pillar 10 to the position corresponding to the outer periphery shown in FIG. 2 as 100. As shown in FIG. 5, when the pillar side slit 11 is moved to the peripheral portion side, it is seen that the pillar side end of the vibration region is moved from the center of the vibrating membrane to the peripheral portion side. Therefore, the shape of the vibrating portion 13 changes, and thereby the vibration characteristics changes. In this case, the area of the vibrating portion 13 decreases, and thereby the relative amplitude amount becomes small. In order to obtain desired vibration characteristics, it is preferable to determine an arrangement of the pillar side slit 11. Of course, a movement of the pillar side slit 11 to the center side of the vibrating membrane 3 also causes a change in the shape of the vibrating portion 13 and thereby a change in the vibration characteristics. Further, a change in the arrangement of the peripheral portion side slit 12A also causes a change in the shape of the vibrating portion 13 and thereby a change in the vibration characteristics. Therefore, the shape and arrangement are changed depending on desired vibration characteristics. A case for the vibrating membrane B will be described below.

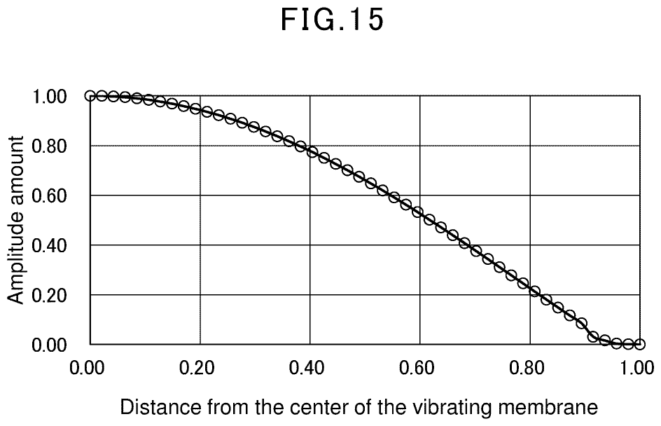

FIG. 6 is a view explaining the vibration characteristics of the vibrating portion 13 in the MEMS element 100 of the present embodiment comprises the vibrating membrane B, in comparison to the vibration characteristics of the vibrating membrane 33 of the MEMS element 300 in the conventional example explained in FIG. 15. In FIG. 6, each of the amplitude amounts is represented as a relative amplitude amount assuming that each of the maximum amplitudes is 1.00. The distance from the center of the vibrating membrane represents a relative distance assuming that the center of the vibrating membrane is 0.00 and the position corresponding to the outer periphery shown in FIG. 2 is 1.00.

As shown in FIG. 6, in the typical MEMS element 300 shown as a conventional example, the amplitude amount is the largest at the center of the vibrating membrane 33 and becomes smaller toward the peripheral portion. That is, it can be said that the region that can be expressed as a vibrating portion range from the central portion to a certain distance, and the region around the periphery does not function as the vibrating portion. Meanwhile, it is seen that, in the MEMS element 100 of the present embodiment, the whole region between the pillar side slit 11 and the peripheral portion side slit 12A of the vibrating membrane vibrates in a relatively uniform manner and functions as a vibrating portion.

In the present embodiment, each of four vibrating portions 13 operates as a movable electrode as shown in FIG. 2, and the fixed electrode is constituted by four fixed electrode portions 14 as shown in FIG. 3. Therefore, a signal that is output from each of the vibrating portions 13 and the fixed electrode portions 14 becomes small. However, the plurality of vibrating portions 13 are provided, and an area displaced generally in parallel relative to the fixed electrode portions 14 in the radial direction of the vibrating membrane 3 as shown in FIG. 6 is increased in each of the vibrating portions 13. Meanwhile, an area where the fixed electrode portions 14 are not formed is decreased as the result of division. However, in an example of the present embodiment shown in FIG. 3, for example, a decreased area of the fixed electrode portions 14 is significantly small, because the diameter of the portion corresponding to the back chamber 9 of the vibrating membrane 3 is 1800 μm, but on the other hand, a dimension of a region where the fixed electrode portions 14 are not formed therebetween is about 20 μm. Further, the region where the fixed electrode portions 14 are not formed is also a region where the vibrating portions 13 are not formed. Accordingly, a sufficiently high sensitivity can be obtained by the MEMS element 100 of the present embodiment provided with the plurality of vibrating portions 13 and the plurality of fixed electrode portions 14, in which the vibrating portions 13 are displaced in parallel to the fixed electrode portions 14 in the radial direction of the vibrating membrane 3.

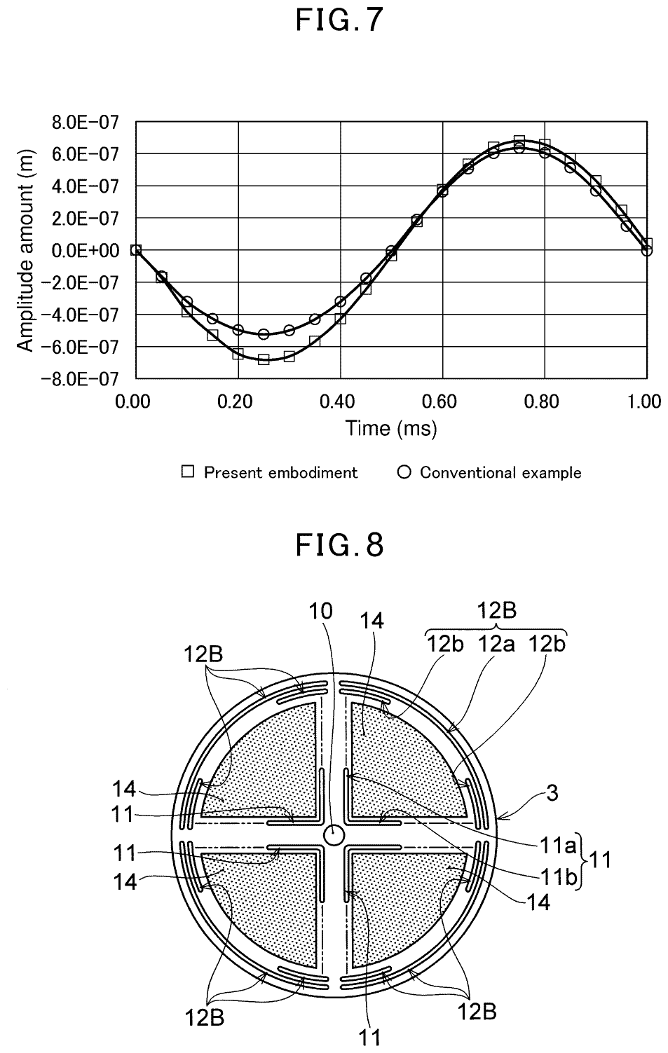

Further, FIG. 7 shows a change in amplitude amount when a sound pressure of 130 dB is applied to the vibrating membrane 3 (vibrating membrane B) in the MEMS element 100 of the present embodiment and the vibrating membrane 33 in the conventional MEMS element 300, respectively. The amplitude amounts are not significantly different between the vibrating membrane B of the present embodiment and the conventional vibrating membrane. However, comparing the changes in amplitude amount, it is seen that the vibrating membrane of the present embodiment is amplified more symmetrically. In this way, the AOP is improved in the MEMS element 100 of the present embodiment in which the vibrating portions 13 of the vibrating membrane 3 including a movable electrode is displaced generally in parallel to the fixed electrode portions 14. Further, in a case where the vibrating membrane 3 is constituted by a material having a small spring constant that facilitates vibration of the vibrating membrane 3, a force applied to each of the vibrating portions 13 becomes small when a bias voltage is applied between the fixed electrode portions 14 and the movable electrode, and thereby distortion of a detected signal becomes small, so that the AOP can be improved. It should be noted that there is no concern of an excessive vibration of the vibrating membrane 3 and the like even in the case of the vibrating membrane 3 having a small spring constant in the present embodiment, since the vibrating membrane 3 is provided with the pillar 10.

Furthermore, in the MEMS element 100 of the present embodiment, noise characteristics can be improved by a configuration in which the fixed electrode 5 is constituted by a plurality of fixed electrode portions 14 and a plurality of variable capacitance elements constituted by one vibrating portion 13 and one fixed electrode portion 14 are connected in parallel. A total noise Nₜₒₜ obtained by summing noises from n pieces of variable capacitance elements (the fixed electrode portions 14) when divided from the fixed electrode 5 can be represented by the following Equation (1).

$${N}_{tot}^{2} = n \times {( \frac{{N}_{0}}{n} )}^{2} \qquad Equation ( 1 )$$

Here, No represents a noise of the variable capacitance elements in a case where the fixed electrode is not divided.

Equation (1) implies

$${N}_{tot} = \frac{{N}_{0}}{\sqrt{n}} \qquad Equation ( 2 )$$

and a noise is reduced depending on a divided number of the fixed electrode.

In this way, with the fixed electrode 5 constituted by the plurality of fixed electrode portions 14, no drop in output voltage occurs and the noise can be reduced. In the case where the fixed electrode 5 is divided into n pieces of the fixed electrode portions 14, the noise can be represented by Equation (2), and thus a signal-to-noise ratio SNRₜₒₜ is represented as

$${SNR}_{tot} = ( \frac{{V}_{0}}{{N}_{0}} ) \times \sqrt{n} \qquad Equation ( 3 )$$

It should be noted that Vₒ is a detection signal in the MEMS element 100 of the present embodiment. As described above, it is seen that the drop in voltage of the detection signal due to the division of the fixed electrode 5 into n pieces is negligibly small, and that the SNR is improved as the fixed electrode 5 is divided into n pieces. In a case where the fixed electrode 5 is divided into four pieces (n=4), for example, the SNR of the MEMS element 100 in which fixed electrode 5 is divided can be improved twofold, i.e., the SNR characteristics can be improved by 6 dB, compared to the SNR of a MEMS element in which a fixed electrode 5 is not divided.

### Embodiment 2

Then, Embodiment 2 of the MEMS element in the present disclosure is explained. FIG. 8 corresponds to FIG. 3 in the above-described Embodiment 1, is a schematic plan view explaining an arrangement of vibrating membrane portions and fixed electrode portions in the MEMS element of the present embodiment, and is a view explaining an arrangement of a vibrating membrane 3 on which the pillar 10, pillar side slits 11, and peripheral portion side slits 12B are disposed, and fixed electrode portions 14. Also in the present embodiment, the back chamber 9 formed in the substrate 1 has a circular shape, and the outer periphery in FIG. 8 corresponds to the outer periphery of the back chamber 9 in the substrate 1. In the MEMS element of the present embodiment shown in FIG. 8, only a shape of the peripheral portion side slits 12B is different from that in the MEMS element 100 explained in the above-described Embodiment 1 shown in FIG. 3. Accordingly, a cross-sectional shape of the MEMS element in the present embodiment can be represented as the schematic cross-sectional view shown in FIG. 1.

A detailed description is given referring to one vibrating portion 13 as an example. In a region on the upper right side of the pillar 10 of the vibrating membrane 3 shown in FIG. 8, the pillar side slit 11 constituted by a first slit portion 11a and a second slit portion 11b is formed. Further, a peripheral portion side slit 12B constituted by a third slit portion 12a and a fourth slit portion 12b is formed. The third slit portion 12a corresponds to the peripheral portion side slit 12A shown in FIG. 2 and FIG. 3. In the present embodiment, the fourth slit portion 12b is disposed on the pillar 10 side of the third slit portion 12a, and the third slit portion 12a and the fourth slit portion 12b constitute the peripheral portion side slit 12B.

Since a region surrounded by an extension line of the first slit portion 11a in the extending direction and an extension line of the second slit portion 11b in the extending direction indicated in a double-dashed line, respectively, in FIG. 8 is defined as one vibrating portion 13, the peripheral portion side slit 12B constituted by the third slit portion 12a and the fourth slit portion 12b is formed so as to open up to a position or near to the position where both ends of the third slit portion 12a and an end of the fourth slit portion 12b intersect with the above-described extension lines. By adding the fourth slit portion 12b, vibration at the peripheral portion of the vibrating membrane 3 is facilitated compared to a case where only the third slit portion 12a is provided.

In this way, the region surrounded by the pillar side slit 11 and the peripheral portion side slit 12B is defined as one vibrating portion 13. As shown in FIG. 8, in a case that a portion of the vibrating membrane 3 corresponding to the back chamber 9, has a circular shape, the pillar 10 is disposed on the vibrating membrane 3 in a manner that the center of the vibrating membrane 3 and the center of the circular pillar 10 match each other, and the pillar side slits 11 and the peripheral portion side slits 12B are disposed to surround the pillar 10 in an evenly spaced manner. In the vibrating membrane 3 configured in this way, four vibrating portions 13 are formed in the regions between the joint portion with the pillar 10 and the peripheral portion.

Also in the present embodiment, a material constituting the vibrating membrane 3, a thickness or a size thereof, and shapes or arrangements of the pillar side slits 11 and the peripheral portion side slits 12B may be set appropriately in a manner that the vibrating portions 13 have desired vibration characteristics.

The fixed electrode portions 14 disposed facing four vibrating portions 13 are disposed in regions facing the regions surrounded by the pillar side slits 11 formed by the first slit portions 11a and the second slit portions 11b as well as the peripheral portion side slits 12B, and each of the plurality of fixed electrode portions 14 is disposed so as to face each of the plurality of vibrating portions 13 (not shown in FIG. 8). It should be noted that FIG. 8 does not show acoustic holes formed in the fixed electrode portions 14 and wires connecting each of the fixed electrode portions 14 and each of the fixed electrode output terminals.

Also in the present embodiment, a signal that is output from each of the vibrating portions 13 and the fixed electrode portions 14 becomes small, since each of four vibrating portions 13 acts as a movable electrode and the fixed electrode is constituted by four fixed electrode portions 14. However, also in the MEMS element of the present embodiment that comprises the plurality of vibrating portions 13 and the plurality of fixed electrode portions 14, in which the vibrating portions 13 are displaced in parallel to the fixed electrode portions 14 in the radial direction of the vibrating membrane 3, a sufficiently high sensitivity can be obtained, similarly to the above-described Embodiment 1.

Further, the AOP is improved since the vibrating portions 13 are displaced generally in parallel relative to the fixed electrode portions 14. Furthermore, the noise characteristics are also improved by forming the fixed electrode with a plurality of fixed electrode portions 14 and configuring a plurality of variable capacitance elements constituted by one vibrating portion 13 and one fixed electrode portion 14 to be connected in parallel.

### Embodiment 3

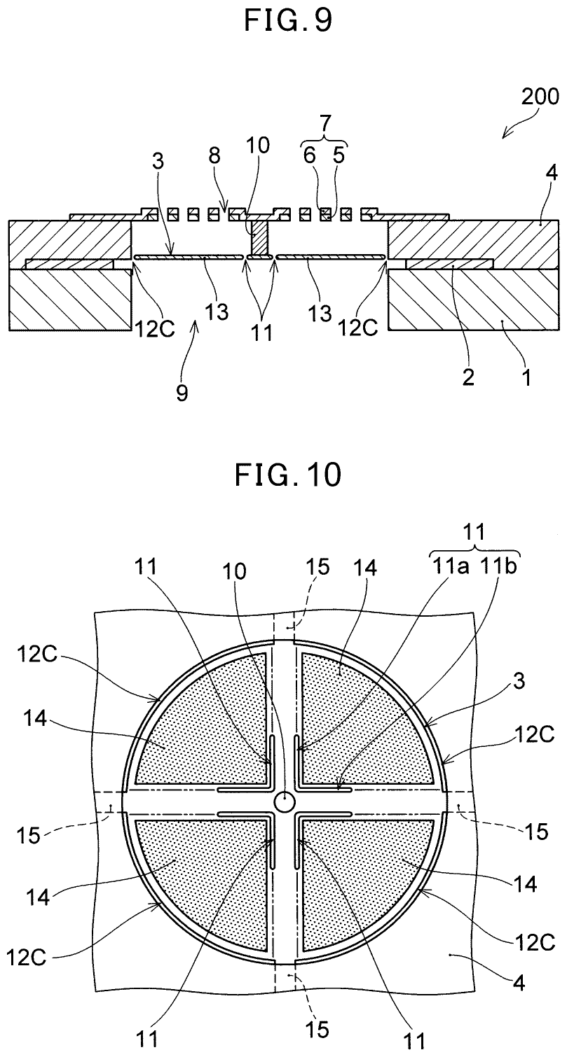

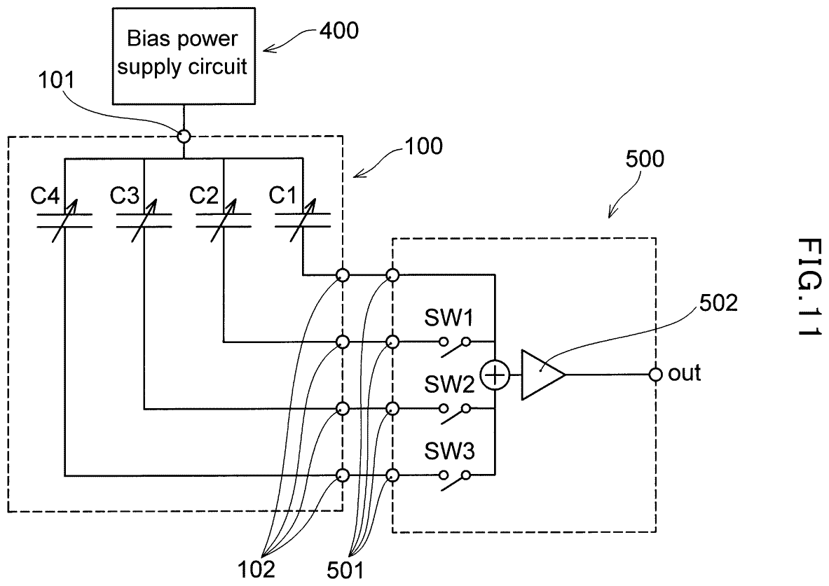

Then, Embodiment 3 of the MEMS element in the present disclosure is explained. In the above-described Embodiments 1 and 2, the peripheral portion side slits 12A, 12B are constituted by through holes formed in the vibrating membrane 3, respectively. Meanwhile, the present embodiment is different from them in that peripheral portion side slits 12C are configured as openings formed of open ends of the vibrating membrane 3 and surfaces facing the open ends as shown in FIG. 9. FIG. 9 is a schematic cross-sectional view of a MEMS element of the present disclosure for explaining Embodiment 3. FIG. 10 is a schematic plan view explaining an arrangement of the vibrating membrane portions and fixed electrode portions in the MEMS element shown in FIG. 9, and a view explaining an arrangement of a vibrating membrane 3 on which a pillar 10 and pillar side slits 11 are disposed, peripheral portion side slits 12C formed of open ends of the vibrating membrane 3 and surfaces facing the open ends, and fixed electrode portions 14. In a MEMS element 200 according to the present embodiment, a support structure of the vibrating membrane 3 including a movable electrode is different and a part of ends of the vibrating membrane 3 is an open end, compared to the MEMS element 100 explained in the above-described Embodiments 1 and 2.

In the MEMS element 200 of the present embodiment, a part of ends of the vibrating membrane 3 facing a substrate 1, an insulating film 2, or a spacer 4 is an open end, and the other parts of the vibrating membrane 3, which are not the open end, are support portions 15. The schematic cross-sectional view shown in FIG. 9 is a cross-sectional view passing through, in FIG. 10, the center of the pillar 10 and the two pillar side slits 11 facing each other with the pillar 10 as the center. Accordingly, the support portions 15 of the vibrating membrane 3 are not shown in FIG. 9, the support portions 15 of the vibrating membrane 3 are laminated on the insulating film 2 in a region not shown, and the spacer 4 is laminated on the support portions 15.

In the MEMS element 200 of the present embodiment, ends of the vibrating membrane 3 are open ends, and surfaces facing the open ends, specifically gaps between the open ends and the spacers 4 are peripheral portion-side slits 12C.

The peripheral portion side slits 12C correspond to the peripheral portion side slits 12A explained in the above-described Embodiment 1. Accordingly, as shown in FIG. 10, in a case where a portion corresponding the back chamber 9 of the vibrating membrane 3 has a circular shape, the pillar 10 is disposed on the vibrating membrane 3 in a manner that the center of the vibrating membrane 3 and the center of the circular pillar 10 match each other, and the pillar side slits 11 and the peripheral portion side slits 12C are disposed to surround the pillar 10 in an evenly spaced manner. In the vibrating membrane 3 configured in this way, four vibrating portions 13 are formed in a region between the joint portion with the pillar 10 and the open ends.

A detailed description is given referring to one vibrating portion 13 as an example. In a region on the upper right side of the pillar 10 of the vibrating membrane 3 shown in FIG. 10, the pillar side slit 11 is formed by a first slit portion 11a and a second slit portion 11b; in which the first slit portion 11a is parallel in the radial direction of the vibrating membrane 3 from the pillar 10 side and extends in the upper direction of the drawing, and the second slit portion 11b is parallel in the radial direction of the vibrating membrane 3 from the pillar 10 side and extends in the rightward direction of the drawing so as to joint with the first slit portion 11a at a joint angle 90°.

By forming the pillar side slit 11, vibration of a portion of the vibrating membrane 3 on the pillar 10 side is facilitated where the vibration is limited by the pillar 10.

Since a region surrounded by an extension line of the first slit portion 11a in the extending direction and an extension line of the second slit portion 11b in the extending direction which are indicated in a double-dashed line, respectively, in FIG. 10 is defined as one vibrating portion 13, the peripheral portion side slit 12C formed of the open end of the vibrating membrane 3 is formed in a manner that both ends of the slit open to a position or near to the position where each of the ends intersects with the above-described extension lines.

In this way, the region surrounded by the pillar side slit 11 and the peripheral portion side slit 12C forms one vibrating portion 13. As shown in FIG. 10, in the case where the portion corresponding to the back chamber 9 of the vibrating membrane 3 has a circular shape, the pillar 10 is disposed on the vibrating membrane 3 in a manner that the center of the vibrating membrane 3 and the center of the pillar 10 match each other, and the pillar side slit 11 and peripheral portion side slit 12C are disposed to surround the pillar 10 in an evenly spaced manner. In the vibrating membrane 3 configured in this way, four vibrating portion 13 are formed in the regions between the joint portion with the pillar 10 and the peripheral portion.

Also in the present embodiment, a material constituting the vibrating membrane 3, a thickness or a size thereof, and shapes or arrangements of the pillar side slits 11 may be set appropriately in a manner that the vibrating portions 13 have desired vibration characteristics.

The fixed electrode portions 14 disposed facing four vibrating portions 13 are disposed in regions facing the regions surrounded by the pillar side slits 11 formed by the first slit portions 11a and the second slit portions 11b as well as the ends of the vibrating membrane 3 that form the peripheral portion side slits 12C, and each of the plurality of fixed electrode portions 14 is disposed so as to face each of the plurality of vibrating portions 13. It should be noted that acoustic holes formed in the fixed electrode portions 14 and a wire that connects each of the fixed electrode portions 14 and the fixed electrode output terminal are not shown in FIG. 10.

Also in the present embodiment, a signal that is output from each of the vibrating portions 13 and the fixed electrode portions 14 become small, since four vibrating portions 13 operate as a movable electrode, respectively, and the fixed electrode 5 is constituted by four fixed electrode portions 14. However, similarly to the above-described Embodiment 1 and Embodiment 2, it is possible to obtain a sufficiently high sensitivity also in the MEMS element 200 of the present embodiment which is provided with the plurality of vibrating portions 13 and the plurality of fixed electrodes 14, in which the vibrating portions 13 is displaced in parallel relative to the fixed electrode portions 14 in the radius direction of the vibrating membrane 3.

In particular, the vibrating membrane 3 of the present embodiment can obtain a sufficiently high sensitivity; since it is less likely to be affected by deformation of the substate 1 and the like because of the small area interfacing with the substate 1 and the like, and an area of the vibrating portions 13 is increased where they can be displaced generally in parallel to the fixed electrode portions 14 in the radius direction of the vibrating membrane 3.

Further, the AOP is improved since the vibrating portions 13 are displaced generally in parallel relative to the fixed electrode portions 14. Furthermore, the noise characteristics are also improved by forming the fixed electrode with the plurality of fixed electrode portions 14 and configuring a plurality of variable capacitance elements each of which is constituted by one vibrating portion 13 and one fixed electrode portion 14 to be connected in parallel.

### Embodiment 4

Then, Embodiment 4 of the MEMS element of the present disclosure is explained. In the above-described Embodiments 1 to 3, it has been explained that the fixed electrode 5 is divided into the plurality of fixed electrode portions 14. In the case where the plurality of fixed electrode portions 14 are provided in this way, a MEMS apparatus can be configured using the MEMS element of the present disclosure with a variously modified connection of each of the fixed electrode portions 14 and a fixed electrode output terminal (not shown). For example, there may be modes where each of the plurality of fixed electrode portions 14 is connected to one of fixed electrode output terminals that are different from each other, or alternatively, two or more of the plurality of fixed electrode portions 14 are connected to a common fixed electrode output terminal.

For example, the MEMS element 100 according to Embodiment 1 is exemplified for the purpose of explanation. In the MEMS element 100 according to Embodiment 1, four fixed electrode portions 14 are formed as shown in FIG. 3. In connecting four fixed electrode portions 14 and the fixed electrode output terminal, how to connect can be changed depending on the number of fixed electrode output terminals.

In the case of one fixed electrode output terminal, all of four fixed electrode portions 14 are connected to the one fixed electrode output terminal.

In the case of two fixed electrode output terminals, one of the fixed electrode portions 14 is connected to one of the fixed electrode output terminals and all of the other remaining three fixed electrode portions 14 are connected to the other fixed electrode output terminal. Alternatively, two of the fixed electrode portions 14 are connected to one of the fixed electrode output terminals and the other two remaining fixed electrode portions 14 are connected to the other fixed electrode output terminal.

In the case of three fixed electrode output terminals, one of the fixed electrode portions 14 is connected to one of the fixed electrode output terminals, the other one of the fixed electrode portions 14 is connected to the other one of the fixed electrode output terminals, and the remaining two of the fixed electrode portions 14 are connected to the other one of the fixed electrode output terminals. In the case of four fixed electrode output terminals, each one of the fixed electrode portions 14 is connected to each one of the fixed electrode output terminals.

In the case where the number of the fixed electrode portions 14 connected to one of the fixed electrode output terminals is set as one, two or more in this way, a level of detection signal can be changed by selecting a detection signal output from the MEMS element 100, except for the case where all of the fixed electrode portions 14 are connected to one fixed electrode output terminal.

For example, the case where any one of the four fixed electrode output terminals is connected to each of four electrode portions 14 is exemplified for the purpose of explanation. A capacitance-type MEMS element detects a displacement of a movable electrode caused by vibration of the vibrating membrane 3 as a capacity change between the movable electrode and a fixed electrode. That is, in the MEMS element 100 according to Embodiment 1, a capacity change between the vibrating portions 13 and the fixed electrode portions 14 becomes a detection signal. Therefore, in the case where each of the fixed electrode output terminals that are different from each other is connected to each of the fixed electrode portions 14, a detection signal is independently output from each of four variable capacitance elements constituted by the vibrating portions 13 and the fixed electrode portions 14.

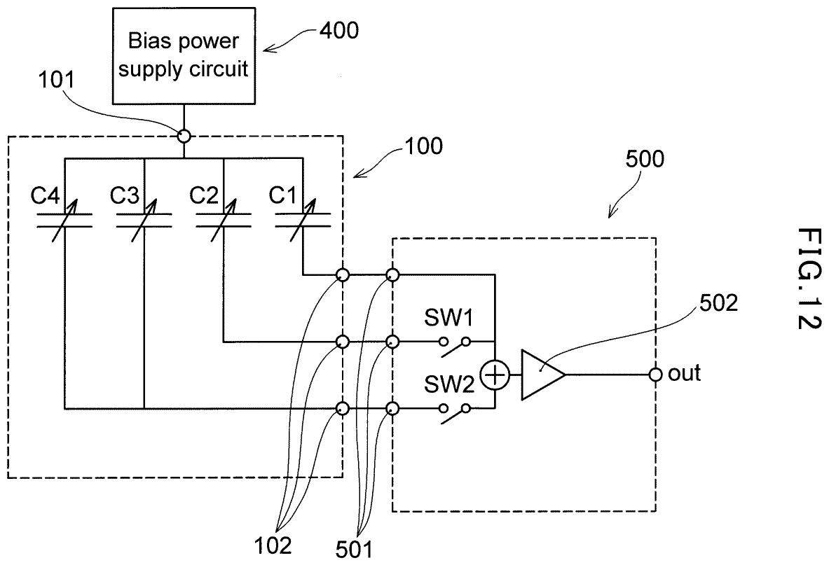

FIG. 11 is a view explaining a MEMS apparatus using the MEMS element of the present disclosure. As shown in FIG. 11, the MEMS element 100 explained in Embodiment 1 has a configuration in which variable capacitance elements C1-C4 constituted by the vibrating portions 13 and the fixed electrode portions 14 are connected in parallel, by connecting four vibrating portions 13 to one movable electrode output terminal 101 and connecting each of four fixed electrode portions 14 to each of different fixed electrode output terminals 102. In order to apply a predetermined amount of bias voltage to the variable capacitance elements C1-C4, a bias power supply circuit 400 is connected to the movable electrode output terminal 101 that is connected to the vibrating portion 13. Meanwhile, each of four fixed electrode output terminals 102, which is connected to each of four fixed electrode portions 14, is connected to each of integrated circuit input terminals 501 of an integrated circuit apparatus 500, in which a signal processing circuit performing a desired signal processing on an output detection signal is formed. The integrated circuit apparatus 500 shown in FIG. 11 is provided with an amplifier 502, in which a signal input from the integrated circuit input terminals 501 is selected through open/close of switches SW1-SW3, and then the selected signal is added and amplified to be output from an output terminal “out”.

When a sound pressure and the like are applied to the MEMS element 100, the vibrating portions 13 vibrate and thereby detection signals are output from the variable capacitance elements C1-C4. The detection signals output from each of the variable capacitance elements C1-C4 have an equal value.

Generally, a maximum input voltage is set to the integrated circuit apparatus 500. For example, this maximum input voltage is determined depending on a power supply voltage of the integrated circuit apparatus 500. As long as a voltage range of a detection signal output from the MEMS element 100 is at the maximum input voltage or less, no problem occurs. However, in some cases, a high maximum input voltage of the integrated circuit apparatus 500 cannot be set to a battery-powered electronic device, and thus a voltage range of a detection signal output from the MEMS element 100 may reach the maximum input voltage or more of the integrated circuit apparatus 500.

When the input detection signal exceeds the maximum input voltage of the integrated circuit apparatus 500, the output signal from the integrated circuit apparatus 500 after signal processing is distorted.

Therefore, it is preferable that a level of an input detection signal can be set in the integrated circuit apparatus 500. In the example shown in FIG. 11, in a case where it is determined that a detection signal exceeds a predetermined maximum input voltage when all of the switches SW1-SW3 are closed and all of the detection signals output from the variable capacitance elements C1-C4 of the MEMS element 100 are added and amplified by the amplifier 502, the level of input detection signal to the integrated circuit apparatus 500 is lowered by opening the switch SW3. In this case, the level can be set as ¾ times of detection signals output from all of the variable capacitance elements C1-C4. Further, the level of input detection signals can be sequentially lowered to ½ times and then ¼ times, by further opening the switch SW2 and then the switch SW1 sequentially. The open/close control of the switches SW1-SW3 can be done with a well-known method by comparing the level of output signal from the amplifier 502 to the level of the reference voltage which has been set in advance, and the like.

In this way, by setting the level of detection signal that is signal-processed by the integrated circuit apparatus 500 depending on a level of input detection signal from the MEMS element 100, signal processing without distortion can be performed even with the integrated circuit apparatus 500 in which a high maximum input voltage cannot be set. In other words, a dynamic range of sound pressure and the like input to the MEMS element 100 can be expanded without deteriorating the AOP.

### Embodiment 5

Next, Embodiment 5 of the MEMS element of the present disclosure is explained. FIG. 12 is a view explaining another MEMS apparatus using the MEMS element of the present disclosure. While the above-described Embodiment 4 explains an example in which any one of four fixed electrode output terminals is connected to each of four fixed electrode portions 14, the number of fixed electrode output terminals is set to three in the present embodiment.

As shown in FIG. 12, the MEMS element 100 explained in Embodiment 1 has a configuration in which variable capacitance elements C1-C4 constituted by vibrating portions 13 and fixed electrode portions 14 are connected in parallel, by connecting four vibrating portions 13 to one movable electrode output terminal 101, connecting each of two fixed electrode portions 14 to each of the independent, fixed electrode output terminals 102, and connecting the other remaining two fixed electrode portions 14 to the other one of the fixed electrode output terminals 102. In order to apply a predetermined bias voltage to the variable capacitance elements C1-C4, a bias power supply circuit 400 is connected to the movable electrode output terminal 101 that is connected to the vibrating portion 13. Meanwhile, three fixed electrode output terminals 102, which are connected to four fixed electrode portions 14, respectively, are connected to input terminals 501 of an integrated circuit apparatus 500, in which a signal process circuit performing a desired signal processing on output detection signals. The integrated circuit apparatus 500 shown in FIG. 12 has an amplifier 502, which selects a signal input from the input terminal 501 through open/close of switches SW1 and SW2 and then adds and amplifies the selected signal.

In the example shown in FIG. 12, in a case where it is determined that a detection signal exceeds a predetermined maximum input voltage when the switches SW1 and SW2 are closed and all of the detection signals output from the variable capacitance elements C1-C4 of the MEMS element 100 are added and amplified by the amplifier 502, the level of input detection signal to the integrated circuit apparatus 500 is lowered by opening the switch SW1. In this case, the level can be set as ¾ times of detection signals output from all of the variable capacitance elements C1-C4. Further, the level of input detection signals can be lowered to ½ times by closing the switch SW1 and opening the switch SW2. Furthermore, the level of input detection signals can be lowered to ¼ times by opening the switches SW1 and SW2. The open/close control of the switches SW1 and SW2 can be done with a well-known method by comparing the level of output signal from the amplifier 502 to the level of the reference voltage which has been set in advance and the like.

In this way, by setting the level of detection signal that is signal-processed by the integrated circuit apparatus 500 depending on a level of input detection signal from the MEMS element 100, signal processing without distortion can be performed even with the integrated circuit apparatus 500 in which a high maximum input voltage cannot be set as in the above-described Embodiment 4, while decreasing the number of switches. That is, a dynamic range of sound pressure and the like input to the MEMS element 100 can be expanded without deteriorating the AOP.

It should be noted that the number of fixed electrode output terminals 102 connected to the fixed electrode portions 14 of the MEMS element 100 may be two so as to enable a similar signal processing. In this case, regarding the MEMS element 100 in the MEMS apparatus shown in FIG. 12, there are two fixed electrode output terminals 102 that are the fixed electrode output terminal 102 connected to the variable capacitance element C1 and the fixed electrode output terminal 102 connected to the variable capacitance elements C2-C4. Further, the integrated circuit apparatus 500 has a configuration in which the integrated circuit input terminal 501 connected to each of two fixed electrode output terminals 102 is provided with switches SW1 and SW2. With such a configuration, the level of detection signal input to the integrated circuit apparatus 500 can be controlled to one time, ¾ times, and ¼ times of the level of detection signal output from all of the variable capacitance elements C1-C4, by controlling an open/close state of two switches SW1 and SW2. Similarly, with a configuration in which two of the variable capacitance elements C1-C4 are connected to each of the fixed electrode output terminals 102, the level of detection signal input to the integrated circuit apparatus 500 can be controlled to one time and ½ times of the level of detection signals output from all of the variable capacitance elements C1-C4.

It should be noted that the level of detection signal can be controlled similarly also in the case where the MEMS element 200 according to Embodiment 3 is used instead of the MEMS element 100, though the case of using the MEMS element 100 according to Embodiment 1 or Embodiment 2 is explained in the above-described Embodiment 4 and Embodiment 5. Further, the MEMS element is not limited to the MEMS element provided with four vibrating portions 13 and the fixed electrode portions 14, and may be a MEMS element provided with a plurality of vibrating portions 13 and a plurality of fixed electrode portions 14, for example, a MEMS element provided with six vibrating portions 13 and the fixed electrode portions 14 may be used. In this case, the level of output signal from the integrated circuit apparatus performing signal processing of detection signals can be controlled appropriately by appropriately setting, depending on the number of fixed electrode portions 14, the number of fixed electrode output terminals 102 connected thereto.

### SUMMARY

(1) A MEMS element of one embodiment of the present disclosure comprises: a substrate comprising a back chamber; a vibrating membrane joined onto the substrate, wherein the vibrating membrane comprises a movable electrode; and a backplate comprising a fixed electrode disposed so as to face the movable electrode, wherein the vibrating membrane: has, at a central portion thereof, a pillar that connects the backplate and the vibrating membrane; and has a plurality of vibrating portions in a region between a portion in which the pillar and the vibrating membrane are joined and a peripheral portion of the vibrating membrane, wherein each of the plurality of vibrating portions is formed by a region surrounded by a pillar side slit by a first slit portion and a second slit portion joined and a peripheral portion side slit disposed at the peripheral portion between an extension line toward the peripheral portion from the first slit portion and an extension line toward the peripheral portion from the second slit portion, the first slit portion and the second slit portion extending in mutually different directions toward the peripheral portion from a portion side in which the pillar and the vibrating membrane are joined, and wherein the fixed electrode has a plurality of fixed electrode portions, each of which is disposed in a region facing each of the plurality of vibrating portions.

According to the MEMS element of the present embodiment, by disposing the pillar that is joined onto the backplate at the central portion of the vibrating membrane, the amplitude at the central portion of the vibrating membrane is suppressed, and further by providing the pillar side slit and the peripheral portion side slit on the vibrating membrane, a vibrating portion with a small difference in amplitude amount between the central portion and the peripheral portion of the vibrating membrane can be formed. A plurality of vibrating portions is formed, so that a large detection signal can be obtained as a whole. Further, because of the division into the plurality of vibrating portions and the plurality of fixed electrode portions, a force applied on each of the vibrating portions becomes small when a bias voltage is applied between the fixed electrode and the movable electrode, and thereby distortion of a detection signal is reduced and a detection signal can be obtained with a reduced noise.
(2) Each of the plurality of fixed electrode portions described above is connected to one of fixed electrode output terminals that are different from each other. Accordingly, the level of detection signal can be changed easily by variously selecting a detection signal output from the MEMS element, when a MEMS apparatus is configured using this MEMS element.
(3) Two or more of the plurality of fixed electrode portions described above are connected to a common fixed electrode output terminal. In this case, except for the case where all of the fixed electrode portions are connected to one fixed electrode output terminal, the other remaining fixed electrode portions may be connected to each of different fixed electrode output terminals, or further two or more fixed electrode portions may be connected to the other common fixed electrode output terminal. This enables an effective switching of the level of detection signals to a desired level.
(4) The pillar side slit is an opening passing through the vibrating membrane and the peripheral portion side slit is an opening passing through the vibrating membrane or an opening between an open end of the vibrating membrane and a surface facing the open end.
(5) The peripheral portion side slit comprises a third slit portion formed along an inner side of the peripheral portion of the vibrating membrane and a fourth slit portion formed along the third slit portion on the pillar side of the third slit portion.

### REFERENCE SIGNS LIST

100, 200, 300 MEMS ELEMENT
400 BIAS POWER SUPPLY CIRCUIT
500 INTEGRATED CIRCUIT APPARATUS
1 SUBSTRATE
2 INSULATING FILM
3 VIBRATING MEMBRANE
4 SPACER
5 FIXED ELECTRODE
6 INSULATING FILM
7 BACKPLATE
8 ACOUSTIC HOLE
9 BACK CHAMBER
10 PILLAR
11 PILLAR SIDE SLIT
11a FIRST SLIT PORTION
11b SECOND SLIT PORTION
12, 12A to 12C PERIPHERAL PORTION SIDE SLIT
12a THIRD SLIT PORTION
12b FOURTH SLIT PORTION
13 VIBRATING PORTION
14 FIXED ELECTRODE PORTION
15 SUPPORT PORTION

1. A MEMS element comprising:
a substrate comprising a back chamber;
a vibrating membrane joined onto the substrate, wherein the vibrating membrane comprises a movable electrode; and
a backplate comprising a fixed electrode disposed so as to face the movable electrode,
wherein the vibrating membrane:
has, at a central portion thereof, a pillar that connects the backplate and the vibrating membrane; and
has a plurality of vibrating portions in a region between a portion in which the pillar and the vibrating membrane are joined and a peripheral portion of the vibrating membrane,
wherein each of the plurality of vibrating portions is formed by a region surrounded by a pillar side slit by a first slit portion and a second slit portion joined and a peripheral portion side slit disposed at the peripheral portion between an extension line toward the peripheral portion from the first slit portion and an extension line toward the peripheral portion from the second slit portion, the first slit portion and the second slit portion extending in mutually different directions toward the peripheral portion from a portion side in which the pillar and the vibrating membrane are joined, and
wherein the fixed electrode has a plurality of fixed electrode portions, each of which is disposed in a region facing each of the plurality of vibrating portions.

2. The MEMS element according to claim 1,
wherein each of the plurality of fixed electrode portions is connected to one of fixed electrode output terminals that are different from each other.

3. The MEMS element according to claim 1,
wherein two or more of the plurality of fixed electrode portions are connected to a common fixed electrode output terminal.

4. The MEMS element according to claim 1,
wherein the pillar side slit is an opening passing through the vibrating membrane and the peripheral portion side slit is an opening passing through the vibrating membrane or an opening between an open end of the vibrating membrane and a surface facing the open end.

5. The MEMS element according to claim 1,
wherein the peripheral portion side slit comprises a third slit portion formed along an inner side of the peripheral portion of the vibrating membrane and a fourth slit portion formed along the third slit portion on a pillar side of the third slit portion.

6. The MEMS element according to claim 2,
wherein the pillar side slit is an opening passing through the vibrating membrane and the peripheral portion side slit is an opening passing through the vibrating membrane or an opening between an open end of the vibrating membrane and a surface facing the open end.

7. The MEMS element according to claim 3,
wherein the pillar side slit is an opening passing through the vibrating membrane and the peripheral portion side slit is an opening passing through the vibrating membrane or an opening between an open end of the vibrating membrane and a surface facing the open end.

8. The MEMS element according to claim 2,
wherein the peripheral portion side slit comprises a third slit portion formed along an inner side of the peripheral portion of the vibrating membrane and a fourth slit portion formed along the third slit portion on a pillar side of the third slit portion.

9. The MEMS element according to claim 3,
wherein the peripheral portion side slit comprises a third slit portion formed along an inner side of the peripheral portion of the vibrating membrane and a fourth slit portion formed along the third slit portion on a pillar side of the third slit portion.
